(19) United States
(12) Patent Application Publication
(10) Pub. No.: US 2008/0121518 A1
(43) Pub. Date: May 29, 2008

(54) PLASMA DEPOSITION PROCESS WITH VARIABLE PROCESS PARAMETERS

(75) Inventor: Luca Ferrario, Ferno (va) (IT)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.R.L., Agrate Brianza (IT)

(21) Appl. No.: 11/944,791

(22) Filed: Nov. 26, 2007

(30) Foreign Application Priority Data
Nov. 27, 2006 (IT) IT MI2006A002271

(51) Int. Cl. H01L 21/36; C23C 4/02

(52) U.S. Cl. 204/192.13; 118/723 R; 427/569

(57) ABSTRACT

A process in a plasma reactor for filling a trench formed in a wafer of semiconductor material, said trench having at least one lateral wall and a bottom wall, wherein the process includes depositing a layer of material in the trench, the layer of material having a non-uniform thickness with an overhang on the at least one lateral wall, at a distance from the bottom wall which is a function of a set of operative parameters of the plasma reactor, and repeatedly varying at least one of the operative parameters for varying the distance of the overhang from the bottom wall.

### BACKGROUND OF THE INVENTION

1. Field of the Invention

The present invention relates to plasma processes, and in particular it relates to the filling of trenches.

2. Discussion of the Related Art

The plasma is a very low pressure gas, to which a strong electromagnetic field is applied so as to cause the ionization thereof. In particular, the plasma is generated in reactors by using a radio frequency power source (RF) that operates at 50 kHz-15 MHz, and is kept at pressure approximately of 0.1-10 Torr; as a result, the plasma has a (relatively) low electronic density, typically ranging from 10⁸ to 10¹⁰ n/cm³.

In High-Density Plasma processes, the plasma is generated by using reactors with one or two RF power sources and is kept at very low pressure (for example, 0.5-50 mTorr) so as to have a high electronic density, typically ranging from 10 μl to 1012 n/cm³.

The plasma reactors are commonly used in various applications; for example, processes based on the plasma are used for realizing STI (Shallow Trench Isolation) structures on a wafer of semiconductor material wherein more electronics components are integrated (for example, floating gate memory cells).

Examples of plasma processes for etching the wafer in order to form trenches adapted for housing the above-mentioned insulating structures and having a significantly large aspect ratio between a length and a width are described in “The benefits of process parameter ramping during the plasma etching of high aspect ratio silicon structures” of Hopkins et al. and in the US patent application US 2005/0070117 of Jacobs et al. Both the documents propose etching methods wherein one or more process parameters (such as the plasma pressure in the reactor and/or the flow of the gas to be ionized) are changed during the process in order to optimise the profile of the trench (for example, in order to reach a desired depth).

Moreover, several methods are known in the art for depositing a layer of material on the wafer; for example, a layer of insulating material (such as silicon oxide) is deposited on the walls of the trenches formed in the wafer of semiconductor material by exploiting HDP CVD (High Density Plasma Chemical Vapor Deposition) processes. In such processes, the layer of insulating material is deposited by using high density plasma in a reactor wherein precursor elements of the layer to be deposited are injected. Moreover, during the HDP CVD process a sputtering etching—caused by a biasing power source operating with very high frequency, such as 13.56 Mhz—it is simultaneous with the deposition; in such a way, the plasma ions which concur to depose the layer of insulating material contribute at the same time, by means of a sputtering action, to partially remove a portion of the layer being just deposited, thereby improving the uniformity thereof.

In such a case, already at the first phases of the deposition process, opposite overhangs form along the lateral walls of the trench to be filled (in order to form the STI insulating regions). When the growing rate of the layer of material along the lateral walls is higher than that along the bottom wall of the trench, such overhangs may become thicker up to touch each other before the layer which is deposited on the bottom wall may reach them. This causes the formation of a void within the trench which significantly impairs the insulating properties of the obtained insulating structures; for example, the partial filling of the STI-type structures may cause short-circuits among the floating gate memory cells integrated in the wafer.

In order to overcome such a problem, solutions known in the art provide the use of HDP CVD processes using high power (for example, from 5 KW to 17 KW). In such a way, the growing rate of the material along the bottom wall of the trench is higher than that of the lateral walls, so that the trench may be completely filled without any formation of voids. A drawback of such solutions is that the plasma, which is generated at high power, may cause a premature deterioration of the materials of which the plasma reactor is composed and of the electronic devices, being integrated in the wafer, which are directly exposed to the plasma.

An other solution is described in U.S. Pat. No. 6,908,862 wherein there is provided the diversification of the process of filling the trench by means of deposition phases which are alternated to etching phases in order to modify the profile of the deposited material according to the desired characteristics. In other words, each deposition phase (in which relatively low thicknesses of material can be formed, such as some tens of nanometers) is followed by an etching phase of the deposited material (for example, a dry etching using fluorine plasma), which tends to reduce the overhangs so as to avoid the formation of undesired voids. A drawback of such solution consists in the fact that during the process possible layers already existing (for example, layers of silicon oxide) may be corroded or irreversibly altered by fluorine compounds (such as fluoride acid). Moreover, such techniques are hardly usable since they imply a quite complex control of the process phases.

### SUMMARY OF THE INVENTION

At least one embodiment of the present invention proposes a solution, which is based on the idea of changing the position of the overhangs during the deposition process.

In particular, an aspect of the present invention provides a process in a plasma reactor for filling a trench formed in a wafer of semiconductor material; said trench has one or more lateral walls and a bottom wall. The process further includes depositing a layer of material in the trench. Such layer of material has a non-uniform thickness with an overhang on the lateral walls of the trench at a distance from the bottom, which distance is a function of a set of operative parameters of the plasma reactor. The process further includes repeatedly varying at least one of the operative parameters for varying the distance of said overhang from the bottom wall.

Preferably, the layer of material is an insulating layer.

According to an embodiment, the operative parameters are varied with a frequency higher than 5*10⁻³ s⁻¹.

Advantageously, it is provided to increase the distance of each overhang from the bottom wall of the trench.

A suggested choice comprises varying a deposition parameter (based on the ratio between the removing rate and the deposition rate).

According to another embodiment, a reduction of said deposition parameter is provided.

Typically, the reactor is provided with different power sources, one (or more) with low frequency and one (or more) with high frequency (which provide radiations with respective first and second power densities); in such case, the first power density, the second power density or both are changed.

Preferably, the first power density and the second power density are linearly changed.

In an embodiment of the invention, the first power density is increased and the second power density is reduced.

For example, it is provided that the first power density increases from 0.058 W/cm³-0.067 W/cm³ to 0.086 W/cm³-0.096 W/cm³ and that the second power density reduces from 0.048 W/cm³-0.058 W/cm³ to 0.023 W/cm³-0.038 W/cm³.

Typically, such a phase has a duration ranging from 100 s to 180 s.

In another embodiment, during a first sub-phase both the power densities are reduced; subsequently in a second sub-phase the first power density is kept constant and the second power density is reduced.

Preferably, during the first sub-phase the first power density is higher than the second power density.

For example, during the first sub-phase it is provided that the first power density reduces from 0.115 W/cm³-0.173 W/cm³ to 0.04 W/cm³-0.05 W/cm³ and that the second power density reduces from 0.076 W/cm³-0.96 W/cm³ to 0.058 W/cm³-0.06 W/cm³; moreover, during the second sub-phase the first power density is kept constant at a value ranging from 0.058 W/cm³-0.096 W/cm³ and that the second power density reduces from 0.048 W/cm³-0.05 W/cm³ to 0.029 W/cm³-0.03 W/cm³.

As further enhancement, the first sub-phase lasts from 10 s to 30 s while the second sub-phase lasts from 40 s to 150 s.

Moreover, a plasma reactor is proposed for performing such a process.

Another aspect of the present invention provides a corresponding software for controlling the process in a plasma reactor.

Another aspect of the invention provides an electronic device obtained with such a process.

A further aspect of the invention provides a system, which includes one or more of such electronic devices.

### BRIEF DESCRIPTION OF THE DRAWINGS

Further features and advantages thereof will be best understood by reference to the following detailed description, given purely by way of a non-restrictive indication, to be read in conjunction with the accompanying drawings. In particular:

FIG. 1 is a schematic illustration of a plasma reactor in which the process of the invention may be used;

FIGS. 2A-2C schematically show a cross-section view of a trench during a process according to an embodiment of the present invention;

FIGS. 3A and 3B show exemplary diagrams relating to electric quantities of the process parameters according to an embodiment of the present invention; and

FIGS. 4A and 4B show exemplificative diagrams relating to electric quantities of the process parameters according to a further embodiment of the present invention.

### DETAILED DESCRIPTION

In the following description, it should be noted that the Figures are not TO scale. Sizes and relative proportions of portions of the drawings have been increased or reduced for the sake of clarity.

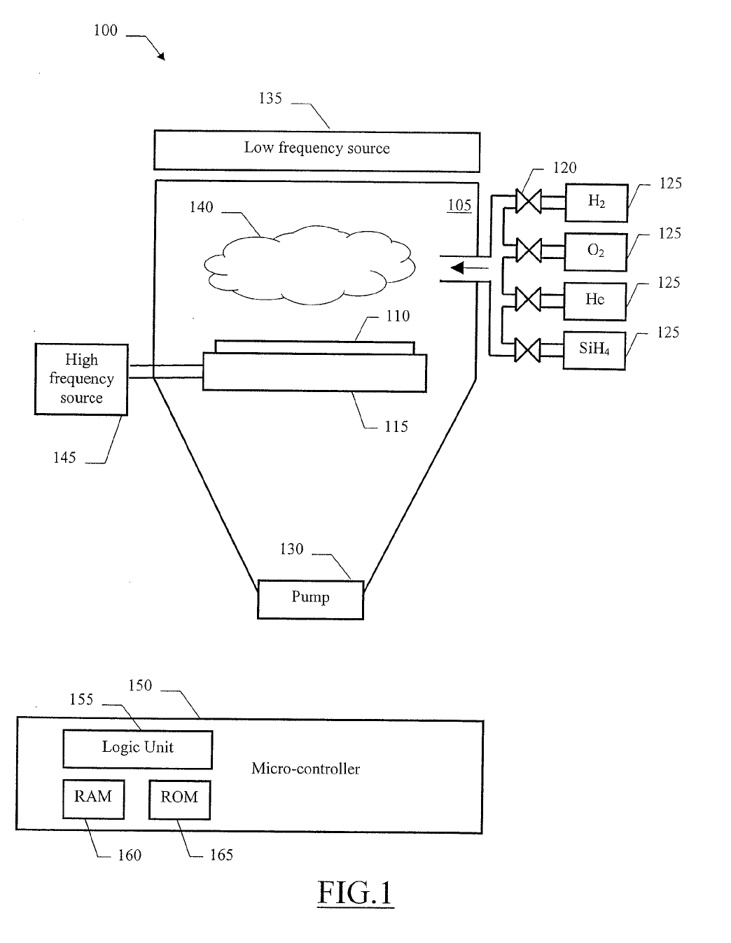

With particular reference to FIG. 1, a reactor 100 for a HDP VCD process is shown. The reactor 100 is used for depositing a layer of insulating material (such as silicon oxide) in such a way to completely fill trenches formed in wafers of semiconductor material.

In particular, the reactor 100 includes a watertight process chamber 105.

The chamber 105 houses a wafer of semiconductor material 110, which is placed on a chuck 115. A set of valves 120 (each one connected to a corresponding gas tank 125) open themselves in the chamber 105. The valves 120 are used for injecting desired amounts of different gases in the chamber 105, so that in the chamber 105 a gas blend forms to be ionized for forming the plasma. In the example at issue, the gases may be hydrogen, helium, oxygen and silane; in particular, the flow of hydrogen varies from 200 a 1400 sccm (standard centimetre cube for second), the flow of helium ranges from 0 a 1200 sccm, the flow of oxygen ranges from 38 a 120 sccm and the flow of silane ranges from 15 a 92 sccm. Moreover, in order to deposit a layer of insulating material having a desired stoichiometry, the ratios between the gas flows injected in the chamber 105 take predetermined values; for example, the ratio between the flow of oxygen and the flow of silane ranges from 0.8 to 3.2, preferably from 1 to 3 and more preferably from 1.3 to 2.8. The gas in the chamber 105 is kept at very low pressure by means of a pump 130 (which is also used for evacuating the chamber 105); for example, the pressure ranges from 0.5 e 20 mTorr, preferably from 0.8 to 17 mTorr, more preferably from 1 to 13 mTorr. A high electromagnetic field is thus applied so as to cause the ionization and/or the dissociation of the gas blend present in the chamber 105. For this purpose, the reactor 100 includes a power source 135. The power source 135 comprises a high frequency generator operating at radio frequency (RF); for example, the frequency may range from 300 kHz to 2 MHz. Thus, a plasma 140 is generated in the chamber 105; the plasma 140 includes positive and negative ions, neutral radicals, free electrons and different compounds obtained from the dissociation and/or combination of the original constituents of the gas blend.

The plasma 140 reacts with the wafer 110 placed on the chuck 115, so as to perform the desired process, in the example at issue the deposition of an insulating layer within the trenches formed in the wafer. At the same time, the wafer 110 is further brought to the desired temperature (higher than 450° C.).

The chuck 115 also operates as an electrode of a biasing power source 145. The biasing source 145 operates at very high frequency, for example in the range from 10 to 30 MHz (such as 13.56 MHz); in some applications, the power source 135 is also denoted as low frequency source (LF) whereas the biasing source 145 is denoted as high frequency source (HF). The biasing source 145 generates a significant sputtering of the ions on the wafer 110, with the result of obtaining a sputtering etching (which occurs at the same time with the deposition process).

The operation of the reactor 100 is controlled by a micro-controller 150. In particular, the micro-controller 150 comprises a logic unit 155 driving the different components of the reactor 100 (such as the power sources 135 and 145) by means of a set of control signals. The logic unit 155 uses a RAM 160 as working memory. The operation of the logic unit 155 is managed by a software, which is stored into a ROM 165.

The morphological and electric characteristics of the deposited layer are affected by the different combinations of the various process parameters, such as the wafer temperature, the composition of the gas, the applied power, the flow of the constituents of the gas blend, the deposition pressure and so on.

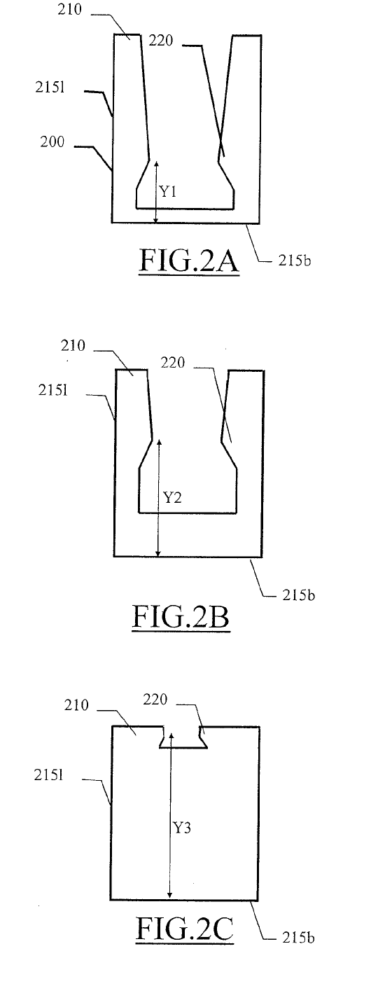

With reference to FIGS. 2A-2C a cross-sectional view of a trench 200 during a filling process thereof with a layer of insulating material 210 is shown. In the example at issue, the trench has lateral walls 2151, which joint perpendicularly with a bottom wall 215b. In particular, since the length of the lateral walls 2151 is significantly higher than the length of the bottom wall 215b, the trench 200 has a high value of the aspect ratio, for example ranging from 2 to 4.5, preferably from 2.5 to 4, more preferably from 3 to 3.5 (for example, 3.2).

Initially (FIG. 2A), the insulating material layer 210 has a non-uniform thickness along the lateral walls 2151 with overhangs 220 (on each lateral wall), which most protruding portion is at a distance Y1 from the bottom wall 215b of the trench 200.

According to an embodiment of the present invention, the filling process of the trench is optimized ramping at least one process parameter during the deposition process. This causes a variation of the plasma properties used for forming the insulating layer 210. In particular, by ramping the process parameters, the position of the overhangs 220 present on the lateral walls 2151 is modified so as to increase the distance thereof from the bottom wall 215b. In such a way, the insulating layer 210 growing from the bottom wall 215b reaches the overhangs 220 before they may touch themselves, without the formation of undesired voids.

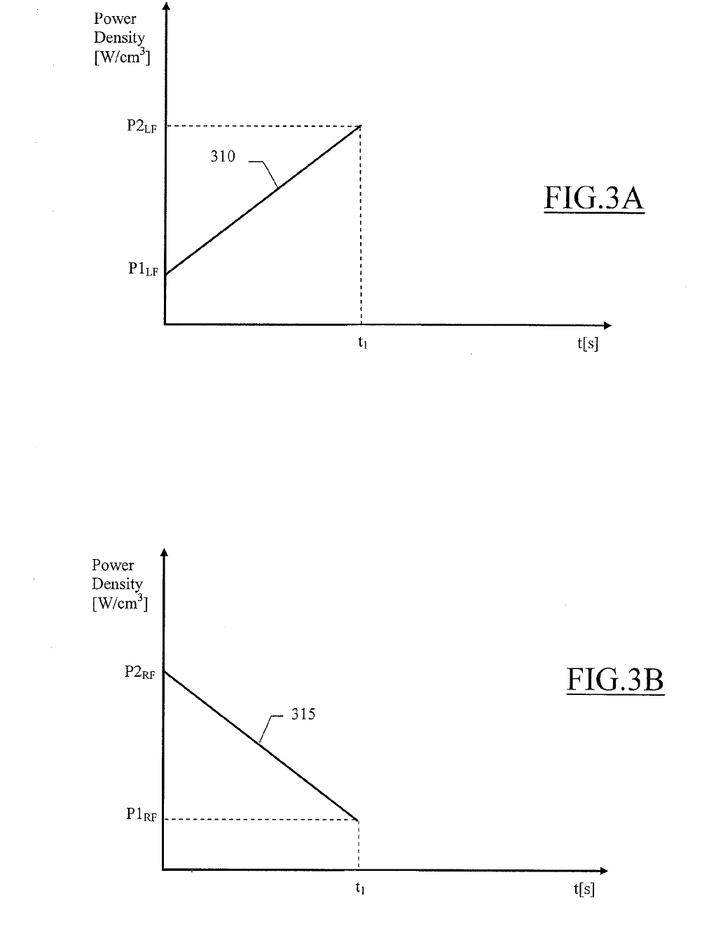

Considering FIGS. 2B and 2C, the overhangs 220 are at a distance Y2 and Y3, respectively, from the bottom wall. In particular, the distance Y1 is lower than the distance Y2 that is lower than the distance Y3. In such a way, as shown in FIG. 3C, the insulating material layer 210 reaches the overhangs 220 before these touch themselves, so that the trench 200 is completely filled.

It should be noted that the solution according to the present invention allows a whole filling of the trenches also in case the trenches have a high aspect ratio. This allows reducing the area occupied within the wafer by the STI insulating structures. In particular, the aspect ratio depends on the minimum size realizable during the integration processes of the electronic devices within the wafer of semiconductor material. For example, in case of CMOS devices (Complementary MOS), the aspect ratio ranges from 2.5 to 3 when the minimum obtainable channel length is 40 nm (technological node 90 nm), whereas it ranges from 3 to 3.5 when the minimum obtainable channel length is 25 nm (technological node 65 nm) and it is higher than four in cases in which the minimum obtainable channel length is equal to 18 nm (technological node 45 nm).

Preferably, the process parameters are continuously changed. In practice, such result is obtained by changing the process parameters with a frequency higher than 5*10⁻² s⁻¹; for example, it is possible to change the process parameters with a frequency ranging from 5*10⁻² s⁻¹ to 20*10⁻² s⁻¹, such as equal to 5*10⁻² s⁻¹. This allows obtaining a continuous distribution of the overhangs 220.

As a further enhancement, the process parameters are changed linearly in time; consequently, it is possible to obtain a uniform profile of the overhangs 220.

Typically, the desired result is obtained by reducing the value of a deposition parameter. In particular, in the deposition processes that use the HDP CVD process, the deposition process is defined by the ratio between the etching rate of the layer due to the sputtering phenomeous and the deposition rate of the same. For example, the deposition parameter ranges from 0.12 to 0.21. In such a way, the overhangs moves from the bottom to the top, thereby allowing the whole filling of the trench 200.

In the example at issue, the changed process parameter is the power density supplied by at least one of the power sources.

With reference to FIG. 3, exemplificative profiles 310 and 315 of the power densities supplied from the low frequency power source and from the high frequency power source, respectively, according to an embodiment of the present invention are shown. The profiles 310 and 315 are reported in a corresponding diagram having the power density [W/cm³] on the axis of the ordinates and the time[s] on the axis of the abscissas.

In particular, the power density provided by the low frequency power source (profile 310) starting from an initial value P1_{LF} linearly increases up to reach a final value P2_{LF} in a time t1. For example, the power density P1_{LF} ranges from 0.056 W/cm³ to 0.069 W/cm³, preferably from 0.057 W/cm³ to 0.068 W/cm³ and more preferably from 0.058 W/cm³ to 0.067 W/cm³, whereas the power density P2_{LF} ranges from 0.084 W/cm³ to 0.098 W/cm³, preferably from 0.085 W/cm³ to 0.097 W/cm³ and more preferably from 0.086 W/cm³ to 0.096 W/cm³. For example, when the chamber has a volume of 52 l, the power density P1_{LF} is obtained by applying a power ranging from 2.91 kW to 3.58 kW, preferably from 2.96 kW to 3.53 kW and more preferably from 3 kW to 3.5 kW, whereas the power density P2_{LF} is obtained by applying a power ranging from 4.3 kW to 5.1 kW, preferably from 4.42 kW to 5.kW and more preferably from 4.4 kW to 4.9 kW.

The time t1 ranges from 80 s to 200 s, preferably from 90 s to 190 s and more preferably from 100 s to 180 s.

The power density provided by the high frequency biasing source (profile 315) starting from an initial value P2_{RF} linearly reduces down to reach a final value P1_{RF} (in the time t1). For example, the power density P2_{RF} ranges from 0.046 W/cm³ to 0.06 W/cm³, preferably from 0.047 W/cm³ to 0.059 W/cm³ and more preferably from 0.048 W/cm³ to 0.058 W/cm³, whereas the power density P1_{RF} ranges from 0.021 W/cm³ to 0.40 W/cm³, preferably from 0.022 W/cm³ to 0.039 W/cm³ and more preferably from 0.023 W/cm³ to 0.038 W/cm³.

It should be noted that the power densities do not exceed some tens of mW/cm³. This allows avoiding the deterioration of the plasma reactor and of the electronic devices integrated in the wafer, which are directly exposed to the plasma.

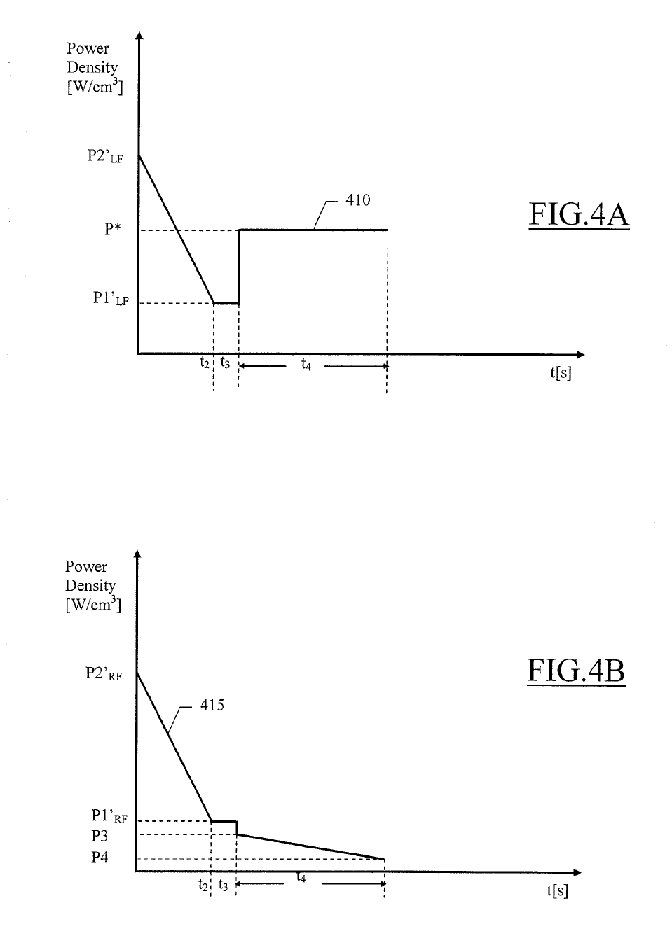

Finally, with reference to FIG. 4, exemplary profiles 410 and 415 of the power densities provided by the low frequency power source and by the high frequency power source, respectively, according to a further embodiment of the present invention are shown. Similarly to what is shown in FIG. 3, the profiles of the power densities 410 and 415 vary linearly during a first sub-phase of the deposition process in a time t2.

In particular, the power density provided by the low frequency power source (profile 410) starting from an initial value P2′_{LF} linearly reduces down to reach a final value P1′_{LF}. For example, the power density P2′_{LF} ranges from 0.113 W/cm³ to 0.175 W/cm³, preferably from 0.114 W/cm³ to 0.174 W/cm³ and more preferably from 0.115 W/cm³ to 0.173 W/cm³, whereas the power density P1′_{LF} ranges from 0.038 W/cm³ to 0.052 W/cm³, preferably from 0.039 W/cm³ to 0.051 W/cm³ and more preferably from 0.040 W/cm³ to 0.050 W/cm³.

The power density provided by the high frequency source (profile 415) starting from an initial value P2′_{RF} linearly reduces down to reach a final value P1′_{RF} (in the same time t2). For example, the power density P2′_{RF} ranges from 0.074 W/cm³ to 0.098 W/cm³, preferably from 0.075 W/cm³ to 0.097 W/cm³ and more preferably from 0.076 W/cm³ to 0.096 W/cm³, whereas the power density P1′_{RF} ranges from 0.056 W/cm³ to 0.062 W/cm³, preferably from 0.057 W/cm³ to 0.061 W/cm³ and more preferably from 0.058 W/cm³ to 0.06 W/cm³.

The time t2 ranges from 5 s to 40 s, preferably from 9 s to 35 s and more preferably from 10 s to 30 s.

After a transition phase t3 (about 2-5 s) needed for the stabilization of the plasma and of the power values, the profile of the power density 410 is kept at a constant value P* during a second sub-phase (in a time t4) needed for completing the filling of the trench. For example, the value P* ranges from 0.056 W/cm³ to 0.098 W/cm³, preferably from 0.057 W/cm³ to 0.097 W/cm³ and more preferably from 0.058 W/cm³ to 0.096 W/cm³.

After the same transition phase t3, the power density provided by the high frequency power source (profile 415) linearly reduces from a value P3 to a final value P4 (in the same time t4). For example, the power density P3 ranges from 0.046 W/cm³ to 0.052 W/cm³, preferably from 0.047 W/cm³ to 0.051 W/cm³ and more preferably from 0.048 W/cm³ to 0.05 W/cm³, whereas the power density P4 ranges from 0.027 W/cm³ to 0.032 W/cm³, preferably from 0.028 W/cm³ to 0.031 W/cm³ and more preferably from 0.029 W/cm³ to 0.03 W/cm³.

The time t4 ranges from 36 s to 170 s, preferably from 38 s to 160 s and more preferably from 40 s to 150 s.

Similarly to the preceding case, the power densities of the high frequency source take significant low values (for example, of the order of some tens of mW/cm³ in the case of the profile 415) so that the deterioration of the plasma reactor and of the electronic devices integrated in the wafer directly exposed to the plasma is avoided. The power densities of the low frequency power source instead take relatively higher values (for example, of the order of some thousands of mW/cm³); however, such power densities are used in shorter times so as to preserve the plasma reactor and the same devices.

Moreover, the described solution allows filling the trenches completely without any use of etching techniques, so preserving such devices from undesired corrosion phenomena due to the compounds of the plasma ions.

In addition, the variation of the process parameters is easily usable, so simplifying the control of the phases of the deposition process.

Naturally, in order to satisfy local and specific requirements, a person skilled in the art may apply to the solution described above many modifications and alterations. Particularly, although the present invention has been described with a certain level of detail with reference to preferred embodiments thereof, it should be understood that various omissions, substitutions and changes in the form and details as well as other embodiments are possible; moreover, it is expressly intended that specific elements and/or method steps described in connection with any disclosed embodiment of the invention may be incorporated in any other embodiment as a general matter of design choice.

For example, the suggested values of the aspect ratio of the trench are not intended to be limiting.

Similar considerations apply if the trench has a different shape or an equivalent structure, if gases being different or in a different quantity are injected into the reactor or if different pressures are provided.

In any case, other types of material layer to be deposited are possible (such as, for example, silicon nitride), possibly also of non-insulating type.

Moreover, the solution of the invention can be implemented with frequencies of the process parameters variations that are different (even lower than the suggested one).

It is also not excluded the possibility of shifting the overhangs in opposite direction (that is, from the top to the bottom).

Alternatively, other process parameters can be varied, such as, for example, the frequency of the sources, the gas flows, the period of residing of the gas blend in the chamber (either singularly or in combination to each other).

As above, it is also possible to increase the deposition parameter.

Alternative implementations are possible wherein only one of the power densities is varied, or more phases are provided with different variations. Moreover, it is possible that the proposed solution should be implemented in reactors that use more than one power source at low and/or high frequency.

In any case, different profiles of the power densities (for example, having an exponential, quadratic, hyperbolic shape) are possible.

With reference in particular to the embodiment of the FIG. 3, similar considerations apply if the power densities vary in another way.

Moreover, the suggested values of the power density are not intended to be limiting.

In any case, the variation phase of the power densities may have a different duration.

Moving now to the embodiment of the FIG. 4, also in this case the power densities may be varied in different way.

Similar considerations apply if the first and the second sub-phases have different durations.

Similar considerations apply if the plasma reactor has a different structure or include equivalent components.

Moreover, the software used for controlling the plasma reactor (in such a way to implement any embodiment of the invention) may take any form adapted to be used by or in connection with a generic control unit of the plasma reactor. In any case, the solution according to the present invention lends itself to be implemented also with a hardware structure (for example, integrated in a chip of semiconductor material), or with a combination of software and hardware.

The obtained structure (with one or more of such trenches) lends itself to be used in any electronic device (which can be distributed either as a wafer, a bare chip or in package).

Moreover, the so obtained electronic devices can be mounted on intermediate products (such as mother boards); in any case, such devices can be used in complex systems (such as computers).

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A process in a plasma reactor for filling a trench formed in a wafer of semiconductor material, said trench having at least one lateral wall and a bottom wall, wherein the process comprises
depositing a layer of material in the trench, said layer of material having a non-uniform thickness with an overhang on the at least lateral wall, at a distance from the bottom wall which is function of a set of operative parameters of the plasma reactor, and
repeatedly varying at least one of the operative parameters for varying the distance of said overhang from the bottom wall.

2. The process according to claim 1, wherein depositing the layer of material comprises depositing a layer of insulating material.

3. The process according to claim 1, wherein varying the at least one operative parameter comprises:
varying the at least one operative parameter with a frequency higher than 5*10⁻² s⁻¹.

4. The process according to claim 1, wherein varying the at least one operative parameter comprises:
varying the at least one operative parameter for increasing the distance of said overhang from the bottom wall.

5. The process according to claim 1, wherein depositing comprises:
etching the layer of material being deposited by means of a ion sputtering, the operative parameters comprising a depositing parameter being defined according to a ratio between an etching rate of the layer of material being deposited and a deposition rate of the layer of material,
and wherein varying the at least one operative parameter comprises:
varying said deposition parameter.

6. The process according to claim 5, wherein varying said deposition parameter comprises:
reducing said deposition parameter.

7. The process according to claim 4, wherein depositing comprises:
injecting at least one gas into plasma reactor,
applying to the at least one gas a first radiation with a first frequency having a first power density by means of at least a first power source, and a second radiation with a second frequency, higher than the first frequency, having a second power density by means of at least a second power source,
and wherein said varying the at least one operative parameter comprises:
varying said first power density and/or said second power density.

8. The process according to claim 7, wherein said varying said first power density and/or said second power density comprises:
linearly varying said first power density and/or said second power density.

9. The process according to claim 7, wherein varying said first power density and/or said second power density comprises:
increasing the first power density and reducing the second power density.

10. The process according to claim 9, wherein increasing said first power density and reducing said second power density comprises:
increasing the first power density from a first initial value ranging between 0.058 W/cm³ and 0.067 W/cm³ to a first final value ranging between 0.086 W/cm³ and 0.096 W/cm³, and
reducing the second power density from a second initial value ranging between 0.048 W/cm³ and 0.058 W/cm³ to a second final value ranging between 0.023 W/cm³ and 0.038 W/cm³.

11. The process according to claim 9, wherein increasing the first power density and reducing the second power density has a duration ranging from 100 s to 180 s.

12. The process according to claim 7, wherein varying said first power density and/or said second power density comprises:
reducing the first power density and the second power density during a first sub-phase, and
keeping constant the first power density and reducing the second power density during a second sub-phase following the first sub-phase.

13. The process according to claim 12, wherein during the first sub-phase the first power density is higher than the second power density.

14. The process according to claim 12, wherein reducing the first power density and the second power density during the first sub-phase comprises:
reducing the first power density from a first initial value ranging between 0.115 W/cm³ and 0.173 W/cm³ to a first final value ranging between 0.04 W/cm³ and 0.05 W/cm³,
reducing the second power density from a second initial value ranging between 0.076 W/cm³ and 0.096 W/cm³ to a second final value ranging between 0.058 W/cm³ and 0.06 W/cm³,
and wherein keeping constant the first power density and reducing the second power density during the second sub-phase comprises:
keeping the first power density at a predetermined value ranging from 0.058 W/cm³ to 0.096 W/cm³, and
reducing the second power density from a further initial value ranging between 0.048 W/cm³ and 0.05 W/cm³ to a further final second value ranging between 0.029 W/cm³ and 0.03 W/cm³.

15. The process according to claim 12, wherein the first sub-phase has a duration ranging from 10 s to 30 s and the second sub-phase has a duration ranging from 40 s to 150 s.

16. A plasma reactor comprising means for performing the process of claim 1.

17. Software for performing the process of claim 1, when the software is executed on a control unit of a plasma reactor.

18. An electronic device comprising a wafer of semiconductor material having at least one trench filled by means of the process of claim 1.

19. A system comprising at least one electronic device according to claim 18.
